(19) United States
(12) Patent Application Publication
(10) Pub. No.: US 2025/0356914 A1
(43) Pub. Date: Nov. 20, 2025

(54) SEMICONDUCTOR STORAGE DEVICE

(71) Applicant: Socionext Inc., Kanagawa (JP)

(72) Inventor: Shinichi MORIWAKI, Yokohama-shi (JP)

(21) Appl. No.: 19/290,986

(22) Filed: Aug. 5, 2025

Related U.S. Application Data
(63) Continuation of application No. PCT/JP2024/007780, filed on Mar. 1, 2024.

(30) Foreign Application Priority Data
Mar. 8, 2023 (JP) 2023-035897

(51) Int. Cl. G11C 11/419; G11C 11/412; H10B 10/00

(52) U.S. Cl. CPC G11C 11/419; G11C 11/412; H10B 10/12; H10B 10/18

(57) ABSTRACT

A semiconductor storage device includes memory cells and a sense amplifier circuit. Each of the memory cells includes p-type drive transistors, n-type load transistors, and p-type access transistors connected to a bit line pair. The sense amplifier circuit includes p-type transistors and n-type transistors.

### CROSS-REFERENCE TO RELATED APPLICATIONS

This is a continuation of International Application No. PCT/JP2024/007780 filed on Mar. 1, 2024, which claims priority to Japanese Patent Application No. 2023-035897 filed on Mar. 8, 2023. The entire disclosures of these applications are incorporated by reference herein.

### BACKGROUND

The present disclosure relates to a semiconductor storage device, more particularly to a static random access memory (SRAM).

The SRAM is widely used as one type of major memories incorporated in a semiconductor integrated circuit device.

Conventionally, as described in Japanese Unexamined Patent Publication No. 2009-176407, for example, a semiconductor storage device in which a transfer gate (access transistor), among transistors constituting an SRAM cell, is formed of a p-type transistor is disclosed.

In conventional techniques including the cited patent document, however, while a circuit diagram of a memory cell having a transfer gate formed of a p-type transistor is shown, a peripheral circuit of an SRAM using such a memory cell has not been disclosed.

An objective of the present disclosure is presenting a peripheral circuit of an SRAM using an SRAM cell that uses a p-type transistor for an access transistor, particularly a circuit related to read of the SRAM.

### SUMMARY

According to the first mode of the disclosure, a semiconductor storage device includes memory cells and a sense amplifier circuit. Each of the memory cells includes a first p-type transistor having a gate connected to a first node, a source connected to a first power supply, and a drain connected to a second node, a first n-type transistor having a gate connected to the first node, a source connected to a second power supply, and a drain connected to the second node, a second p-type transistor having a gate connected to the second node, a source connected to the first power supply, and a drain connected to the first node, a second n-type transistor having a gate connected to the second node, a source connected to the second power supply, and a drain connected to the first node, a third p-type transistor provided between the second node and a first bit line, and having a gate connected to a word line, and a fourth p-type transistor provided between the first node and a second bit line, and having a gate connected to the word line. The sense amplifier circuit includes a fifth p-type transistor having a source connected to the first power supply, and turning on/off based on a sense amplifier enable signal, a sixth p-type transistor having a gate connected to the second bit line via a third node, a source connected to a drain of the fifth p-type transistor, and a drain connected to a fourth node connected to the first bit line, a third n-type transistor having a gate connected to the third node, a source connected to the second power supply, and a drain connected to the fourth node, a seventh p-type transistor having a gate connected to the fourth node, a source connected to the drain of the fifth p-type transistor, and a drain connected to the third node, and a fourth n-type transistor having a gate connected to the fourth node, a source connected to the second power supply, and a drain connected to the third node.

According to the second mode of the disclosure, a semiconductor storage device includes: a memory cell connected to a word line; and a word line driver receiving a clock signal and an address signal as inputs, and turning the word line to a low level according to the clock signal and the address signal. The memory cell includes a first p-type transistor having a gate connected to a first node, a source connected to a first power supply, and a drain connected to a second node, a first n-type transistor having a gate connected to the first node, a source connected to a second power supply, and a drain connected to the second node, a second p-type transistor having a gate connected to the second node, a source connected to the first power supply, and a drain connected to the first node, a second n-type transistor having a gate connected to the second node, a source connected to the second power supply, and a drain connected to the first node, a third p-type transistor provided between the second node and a first bit line, and having a gate connected to the word line, and a fourth p-type transistor provided between the first node and a second bit line, and having a gate connected to the word line. The word line driver includes a fifth p-type transistor having a source connected to the first power supply, and a gate and a drain connected to the word line.

According to the present disclosure, a peripheral circuit of an SRAM using an SRAM cell that uses a p-type transistor for an access transistor is provided.

### BRIEF DESCRIPTION OF THE DRAWINGS

FIG. 1 is a view showing a configuration example of a memory cell array and a driver circuit constituting a semiconductor storage device according to the first embodiment.

FIG. 2 is a view showing a configuration example of a readout circuit constituting the semiconductor storage device according to the first embodiment.

FIG. 3 is a timing chart showing an operation example of the semiconductor storage device according to the first embodiment.

FIG. 4 is a view showing an alteration of the driver circuit according to the first embodiment.

FIG. 5 is a view for explaining the operation of the driver circuit according to the alteration of the first embodiment.

FIG. 6 is a view showing a configuration example of a memory cell array and a driver circuit constituting a semiconductor storage device according to the second embodiment.

FIG. 7 is a view showing a configuration example of a readout circuit constituting the semiconductor storage device according to the second embodiment.

FIG. 8 is a timing chart showing an operation example of the semiconductor storage device according to the second embodiment.

### DETAILED DESCRIPTION

Embodiments of the present disclosure will be described hereinafter with reference to the accompanying drawings. Note that a signal line (node) and a signal passing through the signal line (node) may be described using the same reference character. Similarly, a power supply node and a voltage supplied to the power supply node may be described using the same reference character. Also, in the present disclosure, the term “connection” is used as a concept including the case that components are mutually connected indirectly via an element such as a transistor, in addition to the case that components are mutually connected directly.

### First Embodiment

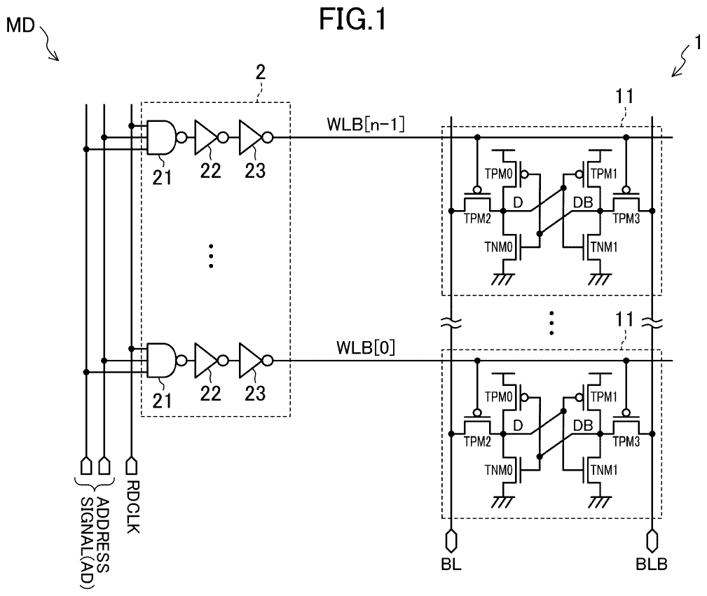

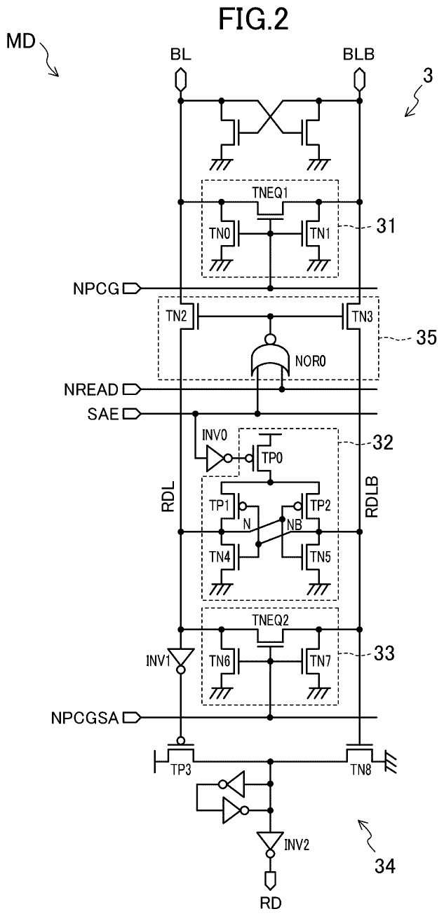

FIGS. 1 and 2 show a configuration example of a semiconductor storage device MD according to this embodiment. The semiconductor storage device MD includes a memory cell array 1 and a word line driver 2 shown in FIG. 1 and a readout circuit 3 shown in FIG. 2.

### [Memory Cell Array]

In this embodiment, the memory cell array 1 includes a plurality of memory cells 11 arranged in an array of n rows (n is a natural number)×m sets (m is a natural number). The memory cells 11 in each row are connected to a corresponding one of word lines WLB[0] to WLB[n−1]. In other words, in this example, the memory cell array 1 is constituted by n word lines WLB[0] to WLB[n−1] and n×m memory cells 11. In FIG. 1, one set out of the m sets of memory cells 11 is shown. In the following description, when the word lines WLB[0] to WLB[n−1] are mentioned with no distinction among them, they may be referred to as the “word lines WLB” simply.

### [Memory Cell]

The memory cell 11 includes p-type drive transistors TPM0 and TPM1, n-type load transistors TNM0 and TNM1, and p-type access transistors TPM2 and TPM3.

In the drive transistor TPM0 (corresponding to the first p-type transistor), the gate is connected to a node DB (corresponding to the first node), the drain is connected to a node D (corresponding to the second node), and the source is connected to the power supply VDD (corresponding to the first power supply). In the load transistor TNM0 (corresponding to the first n-type transistor), the gate is connected to the node DB, the drain is connected to the node D, and the source is connected to the ground VSS (corresponding to the second power supply). That is, the drive transistor TPM0 and the load transistor TNM0 are serially connected between the power supply VDD and the ground VSS.

In the drive transistor TPM1 (corresponding to the second p-type transistor), the gate is connected to the node D, the drain is connected to the node DB, and the source is connected to the power supply VDD. In the load transistor TNM1 (corresponding to the second n-type transistor), the gate is connected to the node D, the drain is connected to the node DB, and the source is connected to the ground VSS. That is, the drive transistor TPM1 and the load transistor TNM1 are serially connected between the power supply VDD and the ground VSS. Also, a latch is formed by the drive transistors TPM0 and TPM1 and the load transistors TNM0 and TNM1.

The access transistor TPM2 (corresponding to the third p-type transistor) is provided between the node D and a bit line BL (corresponding to the first bit line) and has a gate connected to the word line WLB. The access transistor TPM3 (corresponding to the fourth p-type transistor) is provided between the node DB and a bit line BLB (corresponding to the second bit line) and has a gate connected to the word line WLB. Note that, in the following description, the pair of the bit line BL and the bit line BLB may be called the “bit line pair BL, BLB.”

In the memory cell 11, data is held at the nodes D and DB by the latch forming portion made of the drive transistors TPM0 and TPM1 and the load transistors TNM0 and TNM1. When the word line WLB is ‘L’ (Low level), data held at the nodes D and DB are read to the bit line pair BL, BLB via the access transistors TPM2 and TPM3. Hereinafter, a signal of Low level may be simply expressed by ‘L’ and a signal of High level may be simply expressed by ‘H’.

### [Word Line Driver]

The word line driver 2 receives a clock signal RDCLK and an address signal AD as inputs, and turns the target word line WLB to ‘L’ according to the clock signal RDCLK and the address signal AD.

FIG. 1 shows an example of the word line driver 2 constituted by: a NAND circuit 21 that receives the clock signal RDCLK and the address signal AD as inputs; and 2-stage inverters 22 and 23 serially provided between the output of the NAND circuit 21 and the word line WLB. Note that the configuration of the word line driver 2 is not limited to that in FIG. 1, but any other circuit configuration may be used to implement the function of “turning the target word line WLB to ‘L’ according to the clock signal RDCLK and the address signal AD.”

### [Readout Circuit]

The readout circuit 3 shown in FIG. 2 is connected to the bit line pair BL, BLB in the memory cell array 1. The readout circuit 3 is provided for each of the sets of the memory array 1. That is, in this example, m readout circuits 3 are provided for the m sets of memory cells 11. In FIG. 2, one readout circuit 3 is illustrated as an example.

The readout circuit 3 includes a discharge circuit 31, a sense amplifier circuit 32, a data line discharge circuit 33, and an output circuit 34.

### [Discharge Circuit]

The discharge circuit 31 discharges the bit line pair BL, BLB when a discharge signal NPCG is ‘H’.

The discharge circuit 31 includes n-type transistors TNEQ1, TN0, and TN1 (corresponding to the fifth n-type transistor). The transistor TNEQ1 is provided between the bit line BL and the bit line BLB. The transistor TN0 is provided between a node that connects the bit line BL and the transistor TNEQ1 and the ground VSS. The transistor TN1 is provided between a node that connects the bit line BLB and the transistor TNEQ1 and the ground VSS. The discharge signal NPCG is given to the gates of the transistors TNEQ1, TN0, and TN1.

### [Sense Amplifier Circuit]

The sense amplifier circuit 32 amplifies data read to a data line pair RDL, RDLB connected to the bit line pair BL, BLB in response to a sense amplifier enable signal SAE. When the sense amplifier enable signal SAE is ‘H’, the sense amplifier circuit 32 is in an enable state.

The sense amplifier circuit 32 includes p-type transistors TP0, TP1, and TP2 and n-type transistors TN4 and TN5. In the transistor TP0 (corresponding to the fifth p-type transistor), the source is connected to the power supply VDD, and an inverted signal of the sense amplifier enable signal SAE is given to the gate. In the transistor TP1 (corresponding to the sixth p-type transistor), the gate is connected to the data line RDLB (corresponding to the second data line) via a node NB (corresponding to the third node), the source is connected to the drain of the transistor TP0, and the drain is connected to the data line RDL (corresponding to the first data line) via a node N (corresponding to the fourth node). In the transistor TN4 (corresponding to the third n-type transistor), the gate is connected to the node NB, the source is connected to the ground VSS, and the drain is connected to the node N. In the transistor TP2 (corresponding to the seventh p-type transistor), the gate is connected to the node N, the source is connected to the drain of the transistor TP0, and the drain is connected to the node NB. In the transistor TN5 (corresponding to the fourth n-type transistor), the gate is connected to the node N, the source is connected to the ground VSS, and the drain is connected to the node NB.

The signal amplified by the sense amplifier circuit 32 is read from an output terminal RD by the output circuit 34. Specifically, when D=‘H’ and DB=‘L’, ‘L’ is read from the output terminal RD, and when D=‘L’ and DB=‘H’, ‘H’ is read from the output terminal RD. Note here that D indicates the signal at the node D and DB indicates the signal at the node DB. This designation may also be used in the following description.

### [Data Line Discharge Circuit]

The data line discharge circuit 33 discharges the data line pair RDL, RDLB to ‘L’ when a data line discharge signal NPCGSA is ‘H’.

The data line discharge circuit 33 includes n-type transistors TNEQ2, TN6, and TN7. The transistor TNEQ2 is provided between the data line RDL and the data line RDLB. The transistor TN6 is provided between a node that connects the data line RDL and the transistor TNEQ2 and the ground VSS. The transistor TN7 is provided between a node that connects the data line RDLB and the transistor TNEQ2 and the ground VSS. The discharge signal NPCGSA is given to the gates of the transistors TNEQ2, TN6, and TN7.

### [Output Circuit]

The output circuit 34 includes inverters INV1 and INV2, a p-type transistor TP3, and an n-type transistor TN8. The transistor TP3 and the transistor TN8 are serially connected between the power supply VDD and the ground VSS. The data line RDL is connected to the gate of the transistor TP3 via the inverter INV1. The data line RDLB is connected to the gate of the transistor TN8. The node connecting the transistor TP3 and the transistor TN8 is connected to the output terminal RD via the inverter INV2.

The bit line BL is connected to the node N via an n-type transistor TN2 (corresponding to the fifth n-type transistor) and the data line RDL. The transistor TN2 switches between conduction and non-conduction between the bit line BL and the data line RDL based on the sense amplifier enable signal SAE and an NREAD signal (corresponding to the read signal).

The bit line BLB is connected to the node NB via an n-type transistor TN3 (corresponding to the sixth n-type transistor) and the data line RDLB. The transistor TN3 switches between conduction and non-conduction between the bit line BLB and the data line RDLB based on the sense amplifier enable signal SAE and the NREAD signal.

The output of a 2-input NOR circuit NOR0 that receives the sense amplifier enable signal SAE and the NREAD signal as inputs is connected to the gates of the transistor TN2 and the transistor TN3.

### (Data Read Operation)

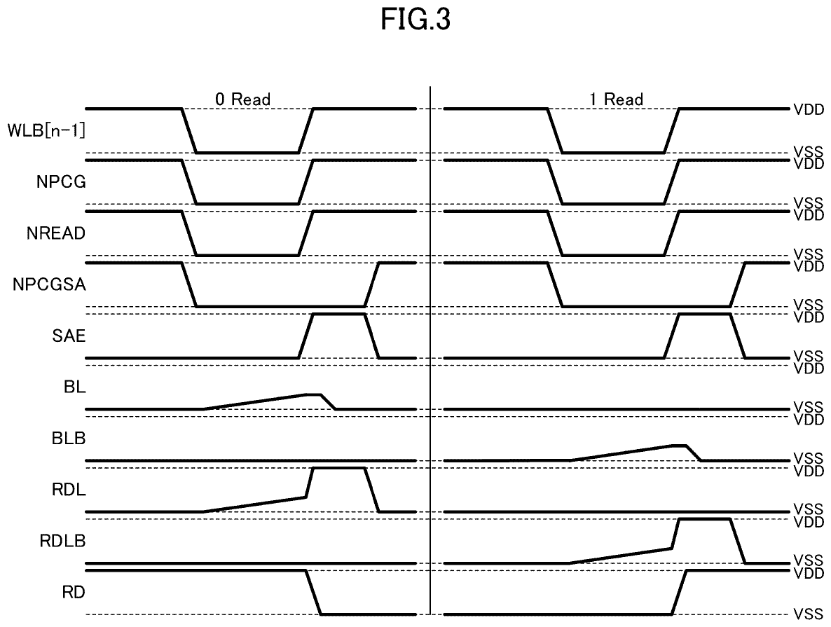

Next, referring to FIG. 3, the data read operation of the memory cell 11 will be described. Note that, hereinafter, for convenience of description, signals may be described using only their reference characters. For example, the signal on the bit line BL may be described using only the reference character “BL”. This also applies to other signals.

First, an operation of reading “0” from the memory cell 11 in the upper stage in FIG. 1 will be described (see left part of FIG. 3).

In the state before the read, D=‘H’ and DB=‘L’ in the memory cell 11. Also, NPCG=NPCGSA=‘H’, and by the action of the discharge circuit 31 and the data line discharge circuit 33, BL=BLB=RDL=RDLB=‘L’.

At the start of the read operation, NPCG=NPCGSA=‘L’ is set, releasing the discharge states of the discharge circuit 31 and the data line discharge circuit 33. Also, WLB[n−1]=‘L’ and NREAD=‘L’ are set. This turns the output signal of the NOR circuit NOR0 to ‘H’, connecting the bit line BL and the data line RDL and connecting the bit line BLB and the data line RDLB. As a result, by the ‘H’ signal stored at the node D, the potentials of the bit line BL and the data line RDL start to rise.

Thereafter, SAE=‘H’ is set, turning the output of the NOR circuit NOR0 to ‘L’. This cuts off the connection between the bit line BL and the data line RDL, and cuts off the connection between the bit line BLB and the data line RDLB. Moreover, the transistor TP0 of the sense amplifier circuit 32 is turned ON, causing the RDL signal and the RDLB signal to be amplified by the sense amplifier circuit 32. This raises the RDL signal up to the power supply voltage VDD, whereby the output of the output terminal RD becomes ‘L’. As a result, “0” is read from the read-target memory cell 11.

Also, together with the setting of SAE=‘H’, WLB[n−1]=NPCG=‘H’ is set. With this, the state of BL=BLB=‘L’ is resumed with the action of the discharge circuit 31.

After the read of data from the output terminal RD, SAE=‘L’ is set, putting the sense amplifier circuit 32 in the non-operation state. Also, NPCGSA=‘H’ is set, whereby the state of the RDL=RDLB=‘L’ is resumed with the action of the data line discharge circuit 33.

Next, an operation of reading “1” from the upper-stage memory cell 11 will be described (see right part of FIG. 3). Description here will be made centering on differences from the operation of reading “0”.

In the state before the read, D=‘L’ and DB=‘H’ in the memory cell 11. Setting of the other signals is similar to that for the operation of reading “0”.

When the discharge states of the discharge circuit 31 and the data line discharge circuit 33 are released and also WLB[n−1]=‘L’ and NREAD=‘L’ are set, the potentials of the bit line BLB and the data line RDLB start to rise by the ‘H’ signal stored in the node DB.

Thereafter, when SAE=‘H’ is set, the RDL signal and the RDLB signal are amplified. This raises the RDLB signal up to the power supply voltage VDD, whereby the output of the output terminal RD becomes ‘H’. As a result, “1” is read from the read-target memory cell 11.

The subsequent operation is similar to that in the operation of reading “0”.

### —Alteration—

Alteration 1 of the semiconductor storage device MD according to the first embodiment will be described.

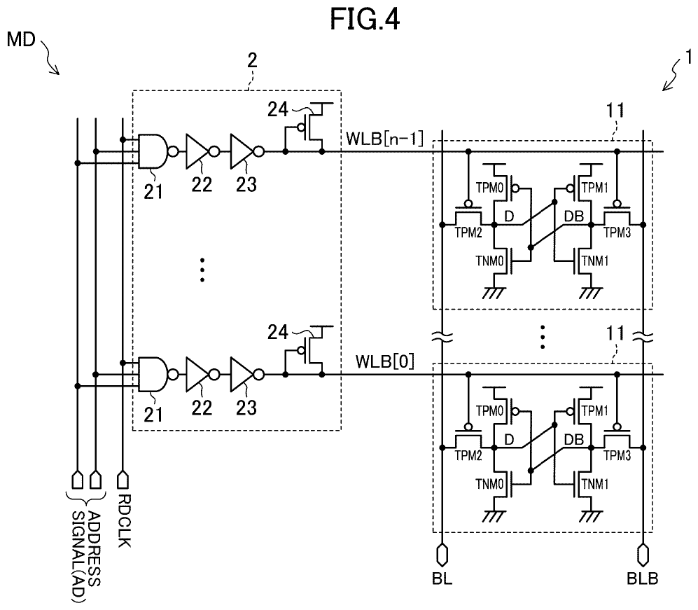

FIG. 4 is a view corresponding to FIG. 1 for this alteration. Description will be made here centering on differences from FIG. 1.

In FIG. 4, the word line driver 2 is different from that in FIG. 1 in having a p-type transistor 24 (corresponding to the fifth p-type transistor) of which the source is connected to the power supply VDD and the gate and the drain are connected to the word line WLB. More specifically, the transistor 24 is connected to each of the word lines WLB[0] to [n−1]. In other words, the word line driver 2 has n transistors 24.

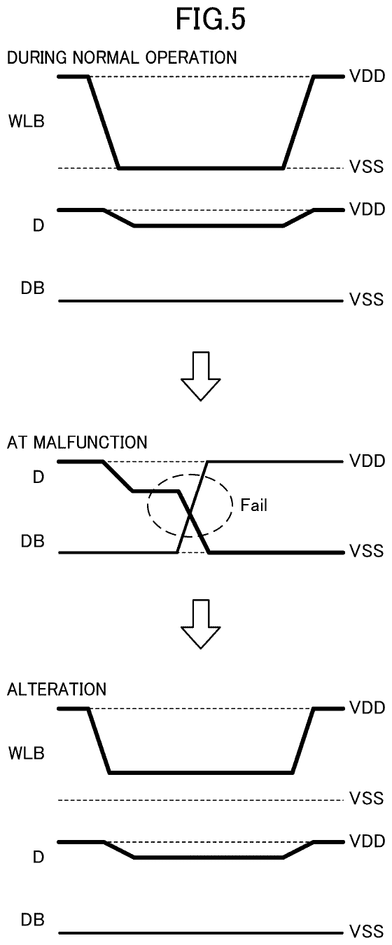

An effect of this alteration will be described with reference to FIG. 5. FIG. 5 shows an example in which D=H and DB=L are stored.

In the semiconductor storage device MD, the read operation is performed when the signal on the word line WLB corresponding to the address signal AD is changed from ‘H’ to ‘L’ with a change of the clock signal RDCLK from ‘L’ to ‘H’.

At the read operation, when the word line WLB becomes ‘L’, electric charge is supplied from the power supply VDD to the previously discharged bit line BL through a route of the drive transistor TPM0, the access transistor TPM2, the bit line BL, and the data line RDL (hereinafter also called the “charge supply route”). This causes, at the node D, a voltage drop due to resistance division in the route from the drive transistor TPM0 to the bit line BL, or a voltage drop due to resistance division in the route from the drive transistor TPM0 to the data line RDL. This voltage drop at the node D is resolved once the signal on the word line WLB returns to ‘H’.

When the ratio of the resistance of the drive transistor TPM0 to the entire resistance of the charge supply route is relatively small, the operation is performed with no trouble in the configuration of FIG. 1 described above (see “During normal operation” in FIG. 5).

On the other hand, when the ratio of the resistance of the drive transistor TPM0 to the entire resistance of the charge supply route is relatively large, the voltage drop at the node D at the time of change of the word line WLB to ‘L’ becomes large. This may cause inversion of the signal at the node D from ‘H’ to ‘L’ and the signal at the node DB from ‘L’ to ‘H’ in the latch forming portion of the memory cell 11, resulting in a malfunction (see “At malfunction” in FIG. 5).

By using the configuration of this alteration, when the word line WLB is ‘L’, the potential of the word line WLB can be made higher than the ground potential VSS (see “Alteration” in FIG. 5). With this, the resistance value of the access transistor TPM2 can be made larger than that in the configuration of FIG. 1. As a result, the ratio of the resistance of the drive transistor TPM0 to the entire resistance of the charge supply route can be made smaller than that in the configuration of FIG. 1. Since this reduces the voltage drop at the node D, normal operation can be secured even when the ratio of the resistance of the drive transistor TPM0 to the entire resistance of the charge supply route becomes relatively large.

### Second Embodiment

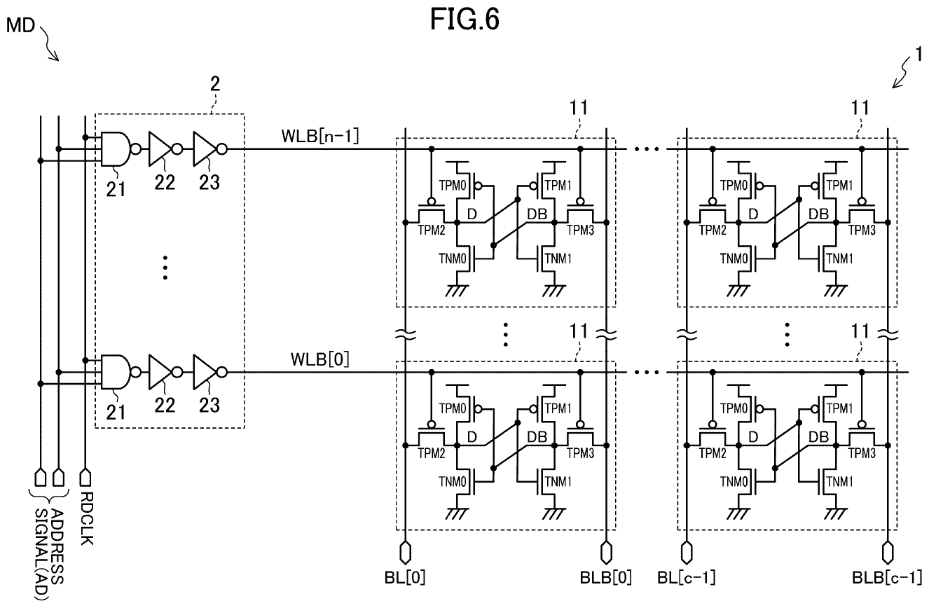

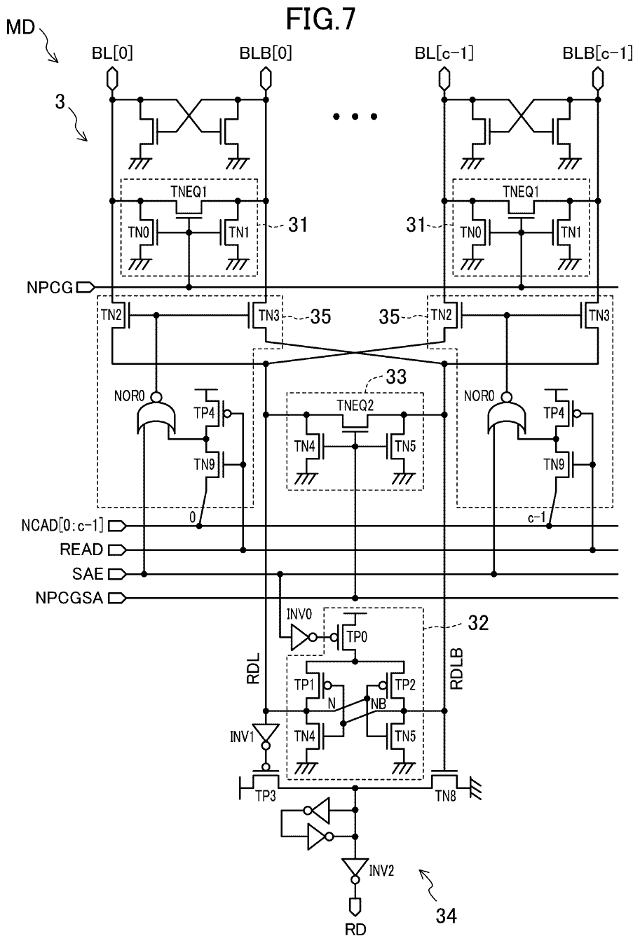

FIGS. 6 and 7 show a configuration example of a semiconductor storage device MD according to this embodiment. The semiconductor storage device MD includes a memory cell array 1 and a word line driver 2 shown in FIG. 6 and a readout circuit 3 shown in FIG. 7. Note that, in FIG. 6, components corresponding to those in FIG. 1 are denoted by the same reference characters. Similarly, in FIG. 7, components corresponding to those in FIG. 2 are denoted by the same reference characters. Description will be made here centering on differences from the first embodiment.

In this embodiment, the memory cell array 1 includes a plurality of memory cells 11 arranged in an array of n rows (n is a natural number)×c columns (c is a natural number)×m sets (m is a natural number). In FIG. 6, one set out of the m sets of memory cells 11 is shown.

As shown in FIG. 6, the memory cells 11 in each row are connected to a corresponding one of word lines WLB[0] to WLB[n−1]. Also, the memory cells 11 in each column are connected to a corresponding one of bit line pairs BL[0] to BL[c−1], BLB[0] to BLB[c−1]. That is, the memory cell array 1 is constituted by n word lines WLB[0] to WLB[n−1], c bit line pairs BL[0] to BL[c−1], BLB[0] to BLB[c−1], and n×c×m memory cells 11.

In the following description, when the word lines WLB[0] to WLB[n−1] are mentioned with no distinction among them, they may be referred to as “word lines WLB” simply. This also applies to the bit lines BL, the bit lines BLB, and the bit line pairs BL, BLB.

As shown in FIG. 7, in the readout circuit 3 in this embodiment, the discharge circuit 31 is provided for each column. That is, the readout circuit 3 includes c discharge circuits 31. The sense amplifier circuit 32, the data line discharge circuit 33, and the output circuit 34 are each provided by one for c columns. Moreover, in addition to the configuration of FIG. 2, the readout circuit 3 includes a column selector circuit 35 for each column.

### [Column Selector Circuit]

The column selector circuit 35 selects a column that is to be the data read target, out of the plurality of columns. Data on the bit line pair BL, BLB in the column (0 to c−1) selected by a column selection signal NCAD[0:c−1] is to be read from the output terminal RD.

To state specifically, the column selector circuit 35 includes n-type transistors TN2, TN3, and TN9, a p-type transistor TP4, and a NOR circuit NOR0.

The transistor TN2 (corresponding to the fifth n-type transistor) is provided between the bit line BL[x] (0≤x≤c−1) and the data line RDL. The transistor TN3 (corresponding to the fifth n-type transistor) is provided between the bit line BLB[x] and the data line RDLB. In the transistor TP4, the source is connected to the power supply VDD and the drain is connected to the drain of the transistor TN9 and to one input of the NOR circuit NOR0. In the transistor TN9, the source is connected to the column selection signal NCAD[x]. The gates of the transistor TP4 and the transistor TN9 are connected to a READ signal. The sense amplifier enable signal SAE is connected to the other input of the NOR circuit NOR0. The output of the NOR circuit NOR0 is connected to the gates of the transistor TN2 and the transistor TN3.

### (Data Read Operation)

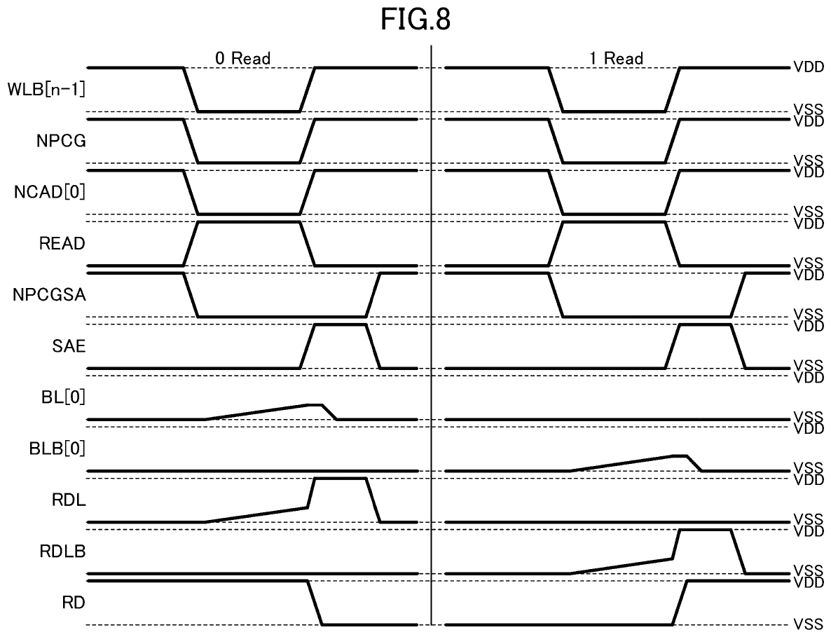

Next, referring to FIG. 8, the data read operation of the memory cell 11 will be described. In this example, an example of data read of the memory cell 11 in the column [0] corresponding to the word line WLB[n−1] and the bit lines BL[0] and BLB[0] (memory cell 11 in the upper left in FIG. 6) will be described. Description will be made centering on differences from the first embodiment (FIG. 3). Note that, while the inverted NREAD signal is used as the read signal in FIG. 3, the non-inverted READ signal is used as the read signal in FIG. 8.

First, an operation of reading “0” from the read-target memory cell 11 will be described (see left part of FIG. 8).

In the state before the read, NCAD[0:c−1]=‘H’ in addition to the state in FIG. 3.

At the start of the read operation, WLB[n−1]=‘L’, READ=‘H’, and NCAD[0]=‘L’ are set. This turns the output signal of the NOR circuit NOR0 in the column [0] to ‘H’, connecting the bit line BL[0] and the data line RDL and connecting the bit line BLB[0] and the data line RDLB. As a result, by the ‘H’ signal stored in the node D, the potentials of the bit line BL[0] and the data line RDL start to rise.

At this time, in the other columns [1:c−1], NCAD[1:c−1]=‘H’ is maintained, so that the bit lines BL[1:c−1] and the data line RDL, and the bit lines BLB[1:c−1] and the data line RDLB, are kept disconnected.

Thereafter, SAE=‘H’ is set, turning the output of the NOR circuit NOR0 to ‘L’. This cuts off the connection between the bit line BL[0] and the data line RDL, and cuts off the connection between the bit line BLB[0] and the data line RDLB. Moreover, the transistor TP0 of the sense amplifier circuit 32 is turned ON, causing the RDL signal and the RDLB signal to be amplified by the sense amplifier circuit 32. This raises the RDL signal up to the power supply voltage VDD, whereby the output of the output terminal RD becomes ‘L’. As a result, “0” is read from the read-target memory cell 11.

The subsequent operation is similar to that in the first embodiment. The state of BL[0]=BLB [0]=‘L’ is resumed with the action of the discharge circuit 31. Also, the state of RDL=RDLB=‘L’ is resumed with the action of the data discharge circuit 33.

Next, an operation of reading “1” from the read-target memory cell 11 will be described (see right part of FIG. 8).

In the state before the read, D=‘L’ and DB=‘H’ in the memory cell 11. Setting of the other signals is similar to that for the operation of reading “0”.

The discharge states of the discharge circuit 31 and the data line discharge circuit 33 are then released. Also, when WLB[n−1]=‘L’, READ=‘H’, and NCAD[0]=‘L’ are set, the potentials of the bit line BLB[0] and the data line RDLB start to rise by the ‘H’ signal stored in the node DB.

Thereafter, when SAE=‘H’ is set, the RDL signal and the RDLB signal are amplified. This raises the RDLB signal up to the power supply voltage VDD, whereby the output of the output terminal RD becomes ‘H’. As a result, “1” is read from the read-target memory cell 11.

The subsequent operation is similar to that in the operation of reading “0”.

Note that the technique in the present disclosure is applicable, not only to the configurations described in the above embodiments, but also to embodiments appropriately subjected to changes, replacements, additions, and omissions from the above embodiments. Also, the components described in the above embodiments can be combined to provide a new embodiment.

For example, the word line driver 2 in the second embodiment may be replaced with the word line driver 2 shown in Alteration 1 of the first embodiment. In this case, also, a similar effect to that in the first embodiment can be obtained.

According to the present disclosure, a peripheral circuit of an SRAM using an SRAM cell that uses a p-type transistor for an access transistor can be provided. The present disclosure is therefore very useful.

1. A semiconductor storage device comprising memory cells and a sense amplifier circuit,
wherein
each of the memory cells includes
a first p-type transistor having a gate connected to a first node, a source connected to a first power supply, and a drain connected to a second node,
a first n-type transistor having a gate connected to the first node, a source connected to a second power supply, and a drain connected to the second node,
a second p-type transistor having a gate connected to the second node, a source connected to the first power supply, and a drain connected to the first node,
a second n-type transistor having a gate connected to the second node, a source connected to the second power supply, and a drain connected to the first node,
a third p-type transistor provided between the second node and a first bit line, and having a gate connected to a word line, and
a fourth p-type transistor provided between the first node and a second bit line, and having a gate connected to the word line, and
the sense amplifier circuit includes
a fifth p-type transistor having a source connected to the first power supply, and turning on/off based on a sense amplifier enable signal,
a sixth p-type transistor having a gate connected to the second bit line via a third node, a source connected to a drain of the fifth p-type transistor, and a drain connected to a fourth node connected to the first bit line,
a third n-type transistor having a gate connected to the third node, a source connected to the second power supply, and a drain connected to the fourth node,
a seventh p-type transistor having a gate connected to the fourth node, a source connected to the drain of the fifth p-type transistor, and a drain connected to the third node, and
a fourth n-type transistor having a gate connected to the fourth node, a source connected to the second power supply, and a drain connected to the third node.

2. The semiconductor storage device of claim 1, comprising:
a memory cell array constituted by a plurality of columns, each column including a unit of the memory cells connected to the common first bit line and the common second bit line; and
a column selector circuit for selecting a column as a data read target out of the plurality of columns.

3. The semiconductor storage device of claim 2, wherein
the column selector circuit includes a fifth n-type transistor configured to connect a column selected out of the plurality of columns to the sense amplifier circuit and, on the other hand, cut off a non-selected column from the sense amplifier circuit.

4. The semiconductor storage device of claim 1, wherein
the first bit line is connected to the fourth node via a fifth n-type transistor and a first data line, the fifth n-type transistor switching between conduction/non-conduction based on the sense amplifier enable signal and a read signal, and
the second bit line is connected to the third node via a sixth n-type transistor and a second data line, the sixth n-type transistor switching between conduction/non-conduction based on the sense amplifier enable signal and the read signal.

5. The semiconductor storage device of claim 1, wherein
a discharge circuit constituted by a fifth n-type transistor is provided between the first bit line and the second bit line.

6. A semiconductor storage device, comprising:
a memory cell connected to a word line; and
a word line driver receiving a clock signal and an address signal as inputs, and turning the word line to a low level according to the clock signal and the address signal,
wherein
the memory cell includes
a first p-type transistor having a gate connected to a first node, a source connected to a first power supply, and a drain connected to a second node,
a first n-type transistor having a gate connected to the first node, a source connected to a second power supply, and a drain connected to the second node,
a second p-type transistor having a gate connected to the second node, a source connected to the first power supply, and a drain connected to the first node,
a second n-type transistor having a gate connected to the second node, a source connected to the second power supply, and a drain connected to the first node,
a third p-type transistor provided between the second node and a first bit line, and having a gate connected to the word line, and
a fourth p-type transistor provided between the first node and a second bit line, and having a gate connected to the word line, and
the word line driver includes
a fifth p-type transistor having a source connected to the first power supply, and a gate and a drain connected to the word line.
